(19) United States
(12) Patent Application Publication
(10) Pub. No.: US 2024/0250650 A1
(43) Pub. Date: Jul. 25, 2024

(54) DIFFERENTIAL AMPLIFIER FOR OPERATING A SENSOR

(71) Applicant: Robert Bosch GmbH, Stuttgart (DE)

(72) Inventors: Lucian Vasile Stoica, Nandlstadt (DE); Francesco Diazzi, Muenchen (DE)

(21) Appl. No.: 18/418,148

(22) Filed: Jan. 19, 2024

(30) Foreign Application Priority Data
Jan. 24, 2023 (DE) 10 2023 200 490.9

(51) Int. Cl. H03F 3/45

(52) U.S. Cl. CPC H03F 3/45179

(57) ABSTRACT

A differential amplifier for operating a sensor. The differential amplifier includes a first two-pole and a second two-pole. A first terminal of the first two-pole is connected to a drain terminal of a current source of a master amplifier of the differential amplifier, and a second terminal of the first two-pole is connected to a first terminal of the second two-pole. A second terminal of the second two-pole is furthermore connected to a source terminal of an input transistor of the master amplifier. The first two-pole includes a first and a second semiconductor switch, which are connected in antiparallel to one another, and the second two-pole includes a third and a fourth semiconductor switch, which are connected in antiparallel to one another.

### CROSS REFERENCE

The present application claims the benefit under 35 U.S.C. § 119 of German Patent Application No. DE 10 2023 200 490.9 filed on Jan. 24, 2023, which is expressly incorporated herein by reference in its entirety.

### FIELD

The present invention relates to a differential amplifier for operating a sensor. In particular, the present invention relates to a space-efficient and low-noise architecture for a differential amplifier, in particular for operating a sensor.

### BACKGROUND INFORMATION

Capacitive MEMS sensors are used in areas such as user terminals, navigation systems, automotive safety systems and stabilization systems for cameras and camcorders. More and more analog functions are being moved along with digital blocks into integrated circuits. As a result, the substrate of the semiconductor is contaminated with clock signals and logical noise. In this mixed signal environment, all analog circuits must function fully differentially. In this way, noises in common mode can be suppressed at the expense of power consumption. Fully differential amplifiers with a continuous time base usually have high-ohmic resistances in the common-mode feedback circuit.

“Analysis and Design of Analog Integrated Circuits,” Grey et al., and “Analog Design Essentials,” Willy Sansen, show corresponding architectural approaches and circuits.

“Balanced output analog differential amplifier circuit,” U.S. Pat. No. 4,742,308, May 3, 1988, and “Common mode signal detector,” U.S. Pat. No. 4,518,870, May 21, 1985, show differential amplifiers of this type.

For example, the differential amplifier is embedded into the charge-to-voltage converter.

In order not to charge the master signal amplifier, the common-mode sensor resistances must have a size of at least several megaohms, which cannot be realized as passive components with an acceptable amount of silicon.

In order to save space and volume, high-ohmic resistances can also be realized by active structures based on a multitude of transistors with a resistive T-network. However, the noise level in these implementations is significantly higher than with simple resistances.

MOS bipolar devices were therefore used to implement high incremental resistances in a feedback network of bandpass filters.

It is an object of the present invention to reduce on the one hand the consumed electrical power and on the other hand the area required for the semiconductor components, without compromising the reliability of the analog signal processing. Within the scope of the present invention, a differential amplifier is provided having a quasi-infinite common-mode sensor resistance based on transistors, connected in antiparallel via diodes, for embedding into, for example, a sensor amplifier, in particular into a charge sensor amplifier.

### SUMMARY

According to an example embodiment of the present invention, a reduction in the charge-to-voltage (C/V) converter semiconductor area and an improvement in the noise properties are provided by using a differential operational amplifier with common-mode feedback circuit including high-ohmic resistances based on amplifiers connected in antiparallel by means of diodes. The antiparallel connection of the amplifiers connected via diodes eliminates the use of high-ohmic passive and active resistances, which are either more expensive due to the required semiconductor area or disadvantageous in terms of their noise propensity. The ohmic common-mode amplifier does not restrict the working range of the input, as a result of which so-called rail-to-rail modes are possible, which increase the reliability of the signal processing of the charge-to-voltage converters. The connection via antiparallel diodes does not charge the differential gain stage and thus helps to preserve the DM gain thereof. The proposed differential amplifier can also be used in other signal processing circuits/architectures.

In other words, a differential amplifier for operating a sensor, in particular a MEMS sensor, is provided in order to achieve the aforementioned object. The capacitive MEMS sensors (e.g., acceleration sensor, gyroscope, pressure sensor, microphones) resolve a mechanical position that changes over time, at a differential capacitor. By means of a charge-to-voltage converter (C/V), the differential capacitance variation is converted into a voltage.

According to an example embodiment of the present invention, the differential amplifier comprises a first two-pole and a second two-pole in a feedback path between a master amplifier and a slave amplifier of the differential amplifier. A first two-pole has a first terminal and a second terminal, wherein the first terminal is connected (in particular directly) to a drain terminal of a current source of the master amplifier of the differential amplifier and the second terminal of the first two-pole is connected to a first terminal of the second two-pole. The second terminal of the second two-pole is connected to a drain terminal of an input transistor of the master amplifier. In other words, the second terminal of the second two-pole is connected to a second drain terminal of a further transistor of the current source of the master amplifier. The first two-pole comprises a first and a second semiconductor switch, which are connected in antiparallel to one another, which second semiconductor switch can be designed as a MOSFET. The second two-pole comprises a third and a fourth semiconductor switch, which are connected in antiparallel to one another. In other words, a source terminal of the first semiconductor switch is connected to a drain terminal of the second semiconductor switch (and vice versa). The same applies to the third and fourth semiconductor switches. By using the two two-poles, a high resistance can be realized without a noise propensity that is common in the related art. In addition, the required semiconductor area (silicon volume) can be kept low.

Preferred developments of the present invention are disclosed herein.

Preferably, the first two-pole can have a first impedance, which is connected in parallel to the first and second semiconductor switches. In other words, the first impedance is connected to the source terminal of the first semiconductor switch and to the drain terminal of the first semiconductor switch. The impedance can be designed as an ohmic and/or complex impedance. The second two-pole can have a second impedance, which is connected in parallel to the third and fourth semiconductor switches. The second impedance can be connected and sized according to the first impedance. The first impedance and/or the second impedance can in particular be provided for operating frequencies above 10 Hz. In this way, the best possible frequency compensation can be realized. The sizing of the first or second impedance can take place as a function of the operating frequency of the differential amplifier.

According to an example embodiment of the present invention, the second terminal of the first two-pole can be connected to a gate terminal of a transistor of a common-mode amplifier of the differential amplifier. The common-mode amplifier can be a slave amplifier of the differential amplifier. The same applies, of course, to the first terminal of the second two-pole since it is coupled to the second terminal of the first two-pole as described above. The voltage level of the feedback path formed from the first and the second two-pole can be set via the input transistor of this slave amplifier.

The input transistor of the slave amplifier can obtain a reference voltage from another circuit. The reference voltage can be set via a mirrored transistor whose gate obtains the voltage from the other circuit.

A third impedance can be connected between the drain terminal and a gate terminal of the current source. The third impedance can likewise be selected as a function of the frequency. As a result, it can influence the frequency behavior of the current source, in particular above 10 Hz.

A fourth impedance can be connected between a further drain terminal on the one hand and the gate terminal as well as a further gate terminal of the current source on the other hand. Via this impedance to be provided or to be sized as a function of the frequency, the behavior of the current source can also be set via the frequency. The third and fourth impedances can also be respectively designed as an ohmic resistance and/or as a complex impedance.

Preferably, according to an example embodiment of the present invention, the second terminal of the second two-pole can additionally be connected to a second drain terminal of the current source of the master amplifier. The second terminal of the second two-pole is preferably connected to a different semiconductor switch of the master amplifier than the first terminal of the first two-pole. Preferably, the gate terminals of these two semiconductor switches can be at the same potential or can be galvanically coupled to one another.

The master amplifier can comprise two further semiconductor switches, which are also referred to as input transistors. Their source terminals can be galvanically coupled to one another and can be set in terms of their working range via a current mirror. The first semiconductor switch of these aforementioned input transistors can be galvanically connected to the first terminal of the first two-pole, and the second drain terminal of the second input transistor can be galvanically connected to the second terminal of the second two-pole. The current source and the input transistors represent the master amplifier of the differential amplifier, which is fed back via the two-poles designed according to the present invention.

In order to generate a particularly high resistance in the feedback path or in the first/second two-pole, the potential of the operating voltage or supply voltage of the differential amplifier can be applied to the substrate. In this way, the diode inherent to the semiconductor switches of the first and second two-poles is switched off. The inherent diode thus cannot conduct and cannot undesirably reduce the resistance.

### BRIEF DESCRIPTION OF THE DRAWINGS

Exemplary embodiments of the present invention are described in detail below with reference to the figures.

FIG. 1 shows a schematic representation of an exemplary embodiment of a differential amplifier according to the present invention.

FIG. 2 shows a detailed view of two semiconductor switches from FIG. 1, which are connected in antiparallel to one another.

### DETAILED DESCRIPTION OF EXAMPLE EMBODIMENTS

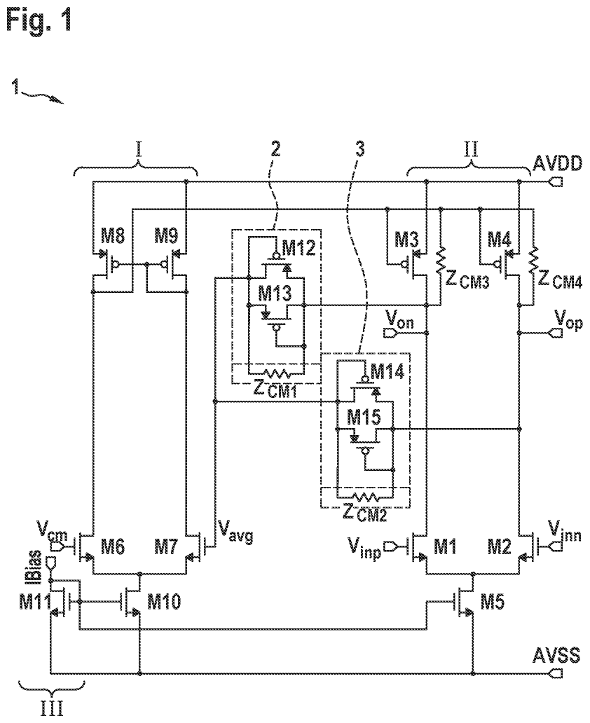

FIG. 1 shows the circuit of a differential amplifier 1 for operating a MEMS sensor. The circuit can be divided into the assemblies of slave amplifier I, master amplifier II, and current mirrors III for operating point setting. These assemblies I, II, III correspond to differential amplifiers of the related art. The slave amplifier I comprises a current mirror comprising two transistors M8, M9, the gates of which are electrically connected to one another. The two remaining transistors M6, M7 of the slave amplifier I serve as input transistors for providing a predefined voltage level of the feedback path, which is discussed below. Strictly speaking, the assembly of the current mirrors III comprises two individual current mirrors, the first of which comprises the transistors M11 and M10, while the second comprises the transistors M11, M5. The reference current iBias is drawn from an external circuit (not shown). Via the current mirrors, the slave amplifier I and the master amplifier II are set to a predefined operating point. The master amplifier II comprises a current source comprising the transistors M3 and M4, the respective source drain impedances Z_{CM3}, Z_{CM4} of which are sized to adapt the differential amplifier 1 to a predefined operating frequency. The drain terminal of the transistor M3 is connected to a first terminal of the first two-pole 2 according to the present invention, the second terminal of which is connected to a first terminal of the second two-pole 3 according to the present invention. The second terminal of the second two-pole 3 is connected to the drain terminal of the transistor M4. The two-poles 2, 3 according to the present invention are surrounded by a dashed border and, for setting the operating point or operating frequency, can be supplemented by impedances Z_{CM2}, which are connected in parallel and surrounded by a dotted border. AVDD denotes the supply voltage. Vₒₙ, Vₒₚ denotes the output voltage (negative and positive) of the differential amplifier 1, while the designation Vᵢₙₚ and Vᵢₙₙ stands for the negative and positive input voltage (sensor output signal). AVSS stands for the electrical ground. The differential amplifier shown in FIG. 1 shows the common-mode control solution according to the present invention and operates as follows: The differential input signal from the capacitance variation is applied to the gate terminals of the transistors M1, M2 as Vᵢₙₙ and Vᵢₙₚ. The DC voltages at the outputs Vₒₚ, Vₒₙ are averaged via antiparallel transistors M12, M13, M14, M15 at the gate of M7. The voltage of the differential amplifier is provided by the differential signal at the outputs Vₒₚ, Vₒₙ. The master amplifier is provided by the transistors M1, M2, M3, M4, M5, wherein M5 can be considered to be part of a current mirror. Common-mode determination is provided by antiparallel transistors M12, M13 and M14, M15, which implement quasi-infinite high-ohmic resistances with a linear characteristic for wide output signal oscillation. The single-stage common-mode feedback circuit (CMFB) is of a time-continuous type and is formed by the transistors M6, M7, M8, M9, M10. Separate clock signals are thus not required for the CMFB. The common-mode reference voltage V_{cm} is provided at the gate of M6. By means of the function of the negative feedback loop of the common-mode feedback amplifier, which compares the common-mode reference voltage V_{CM} as an external reference to the averaged DC voltage V_{avg}, which is provided at the gate of M7 by the transistors M12, M13 and M14, M15, which are connected in antiparallel to one another with respect to their diodes, and regulates the gate voltage of the transistors M3, M4, which represent the current source, with the output voltage at the drain of the transistor M8 so that V_{cm} is equal to the mean value of Vₒₚ and Vₒₙ. In order to maximize the output signal oscillation, the common-mode reference voltage V_{cm} is usually selected centrally between the values of AVDD and AVSS.

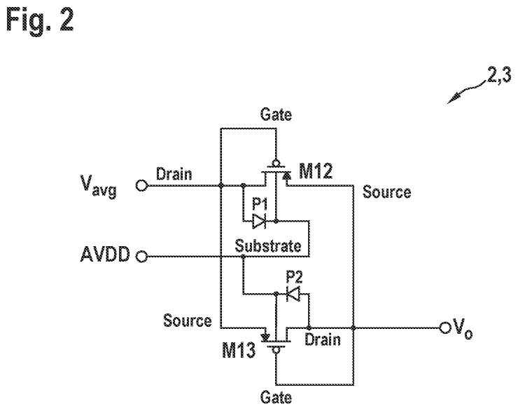

FIG. 2 shows, by way of example, a detailed view and/or a detailed equivalent circuit diagram of the two-poles 2, 3 (see FIG. 1). The supply voltage AVDD is applied to the substrates of the transistors M12, M13 so that the parasitic diodes P1, P2 are switched off (blocked in any case). In comparison to a two-pole 2, 3 designed according to the present invention as shown, a considerably greater resistance with a considerable silicon cost or a considerable silicon area would have to be used in the related art in order to realize low noise. FIG. 2 shows two PMOS transistors M12, M13 in antiparallel connection so that they are alternately conductive when the polarity of the voltage across them changes as follows:

If Vₒ>V_{avg} applies, only PMOS transistor M12 is conductive and PMOS transistor M13 is switched off, and if Vₒ<V_{avg} applies, only PMOS transistor M13 is conductive and PMOS transistor M12 is switched off.

In order the conduction of the parasitic lateral and vertical pnp structures, which are provided in order to prevent in the N-type source and the P-type substrate with the P+ and N+ dopings, the substrate of the PMOS transistors is connected to the highest potential of the circuit (supply voltage AVDD). For small (large) voltage drops across the antiparallel PMOS transistors, the incremental resistance becomes large (small). The incremental resistance of the PMOS transistors, which are connected in antiparallel to one another, is in the order of magnitude of 10⁶ to 10¹² ohms, even if large signal oscillations are applied to the output of the master amplifier so that the master amplifier is not charged, which has the effect that the signal amplification does not decrease.

The bias current (operating point setting) iBias is provided by a different voltage and distributed via the current mirrors M11, M10 and M11, M5 to the slave amplifier I and the master amplifier II. The impedances Z_{CM1}, Z_{CM2} consist of a combination of resistances and capacitors in order to ensure the frequency compensation/loop gain stability of the differential-mode (DM) and common-mode (CM) loops. The transistors M8, M9, M3, M4 can also be realized with different current-mirror/current-source architectures. The transistors M12, M13, M14, M15 can also be implemented as large-ratio (L/W) transistors, which have different gate voltages in triode operating ranges.

What is claimed is:

1. A differential amplifier for operating a sensor, comprising:
a first two-pole including a first semiconductor switch and a second semiconductor switch connected in antiparallel to one another; and
a second two-pole including a third semiconductor switch and a fourth semiconductor switch connected in antiparallel to one another;
wherein
a first terminal of the first two-pole is connected to a drain terminal of a current source of a master amplifier of the differential amplifier, and
a second terminal of the first two-pole is connected to a first terminal of the second two-pole, wherein a second terminal of the second two-pole is furthermore connected to a source terminal of an input transistor of the master amplifier.

2. The differential amplifier according to claim 1, wherein:
the first two-pole includes a first impedance, which is connected in parallel to the first and second semiconductor switches, and
the second two-pole includes a second impedance, which is connected in parallel to the third and fourth semiconductor switches.

3. The differential amplifier according to claim 1, wherein the second terminal of the first two-pole is connected to a gate terminal of a transistor of a common-mode amplifier of the differential amplifier.

4. The differential amplifier according to claim 1, wherein the sensor is a Mems sensor.

5. The differential amplifier according to claim 1, wherein a third impedance is connected between the drain terminal and a gate terminal of the current source.

6. The differential amplifier according to claim 5, wherein a fourth impedance is connected between a further drain terminal on the one hand, and the gate terminal and a further gate terminal of the current source on the other hand.

7. The differential amplifier according to claim 1, wherein the second terminal of the second two-pole is connected to a second drain terminal of the current source of the master amplifier.

8. The differential amplifier according to claim 1, wherein the second terminal of the second two-pole is connected to a first source terminal of an input transistor of the master amplifier, and the first terminal of the first two-pole is connected to a second source terminal of another input transistor.

9. The differential amplifier according to claim 1, wherein:
substrate terminals of the first semiconductor switch and of the second semiconductor switch are galvanically connected to a supply voltage, and/or
substrate terminals of the third semiconductor switch and of the fourth semiconductor switch are galvanically connected to the supply voltage.
